(19) United States
(12) Patent Application Publication
(10) Pub. No.: US 2025/0245268 A1
(43) Pub. Date: Jul. 31, 2025

(54) SYSTEM AND METHOD FOR MANAGING DATA IN DIGITAL TWINS

(71) Applicant: Satavia Limited, Cambridge (GB)

(72) Inventors: James DOBSON, Cambridge (GB); Adam DURANT, Cambridge (GB)

(73) Assignee: Satavia Limited, Cambridge (GB)

(21) Appl. No.: 18/854,641

(22) PCT Filed: Mar. 31, 2023
(86) PCT No.: PCT/IB2023/053248

§ 371 Date: Oct. 7, 2024

(30) Foreign Application Priority Data
Apr. 6, 2022 (GB) 2205015.7

(51) Int. Cl. G06F 16/83; G06F 16/81; G06F 30/20; G08G 5/32

(52) U.S. Cl. CPC G06F 16/83; G06F 16/81; G06F 30/20; G08G 5/32

(57) ABSTRACT

A system including processor(s) configured to: run digital twin(s) of real-world asset(s); receive datasets from data sources, data sources being communicably coupled to the processor(s) via a first application programming interface (API); update the digital twin(s), based on the received datasets; receive, from a user device, a query for obtaining information from the digital twin(s), the user device being communicably coupled to the processor(s) via a second API; process the query to generate a response comprising said information; and send the response to the user device.

### TECHNICAL FIELD

This invention relates to managing large datasets. In particular, though not exclusively, this invention relates to a system and a method which updates and queries datasets in at least one digital twin to generate responses.

### BACKGROUND

With advancements in technology, a shift from manual management of data to computerised management of data has been observed. Such computerised management requires and creates vast amounts of data, which can vary greatly according to the type of data management being carried out. The data may exist as structured or unstructured data and could be in various different formats. Due to the vast volumes of data being available in multiple formats, management of this data to retrieve useful information is difficult.

Recently, various technologies are being used to manage such data and derive meaningful information. One such technology is digital twin technology; wherein virtual representations (i.e., digital twins) are created which replicate real-world objects and processes. Updated using real-time data, the digital twin technology uses simulation, machine learning and reasoning for executing decision-making processes. The digital twin technology allows for a time-efficient analysis of problem statements, such that the problem statements are solved virtually (i.e., in a simulation), instead of being solved physically. However, multiple file formats are not supported with such digital twin technology and there is a limitation to the number of file formats which can be supported by a given digital twin. Because of this, it is difficult to integrate multiple functions and/or software with the digital twin technology.

Lately, some systems have been designed to integrate a plurality of application processing interfaces (APIs) for each type of file format for updating and querying in digital twins. Since one API is used for each type of file format, the system ends up having a lot of APIs which make the system extremely heavy, slowing down query response speeds, and thereby leading to lags. Moreover, such systems do not provide a cohesive solution to integrate usability of different file formats.

Therefore, in light of the foregoing discussion, there exists a need to overcome the aforementioned drawbacks associated with updating and querying datasets in digital twins to generate query responses.

### SUMMARY OF THE INVENTION

A first aspect of the invention provides a system comprising at least one processor configured to:
run at least one digital twin of at least one real-world asset;
receive datasets from a plurality of data sources, the plurality of data sources being communicably coupled to the at least one processor via a first application programming interface (API);
update the at least one digital twin, based on the received datasets;
receive, from a user device, a query for obtaining information from the at least one digital twin, the user device being communicably coupled to the at least one processor via a second API;
process the query to generate a response comprising said information; and
send the response to the user device.

Throughout the present disclosure, the term “processor” refers to hardware, software, firmware, or a combination of these configured to control operation of the system. In this regard, the at least one processor performs several complex processing tasks. The at least one processor is communicably coupled to other components of the system device wirelessly and/or in a wired manner. In an example, the at least one processor may be implemented as a programmable digital signal processor (DSP). In another example, the at least one processor may be implemented via a cloud server that provides a cloud computing service.

Throughout the present disclosure, the term “digital twin” refers to a virtual representation of a given real-world asset, which serves as a real-time digital counterpart. This means that, the at least one digital twin is updated in real-time during its entire lifecycle, depending on changes observed in the at least one real-world asset. Moreover, the at least one digital twin utilises at least simulation, machine learning and reasoning technologies for assisting in decision-making. The term “real-world asset” refers to an object or a process which exists in a real-world. It will be appreciated that the at least one real-world asset is not a data source.

Optionally, the real-world asset has a physical form associated therewith. Herein, the at least one real-world asset may be implemented in a variety of manners, including, but not limited to, an aeroplane in an atmosphere, a submarine underwater, a spaceship in outer space, healthcare operations and patient care, a city, a sport or game. In an example, the at least one real-world asset may be implemented as the aeroplane in the atmosphere. The at least one digital twin, in this case, may be a simulation of the aeroplane for pilot training or flight optimisation. In another example, the at least one real-world asset may be implemented as the city, wherein the digital twin is used by architects to plan the city, or optimise a current plan of the city. Advantageously, utilising the at least one digital twin of the at least one real-world asset minimises risk, reduces costs associated with maintenance, and ensures high levels of accuracy.

Optionally, the at least one processor is configured to run the at least one digital twin of the at least one real-world asset on a digital platform. Herein, the digital platform is optionally based on at least one of: an artificial intelligence (AI) technology, a machine learning (ML) technology, a software analytics technology, an internet of things (IoT) technology.

The term “dataset” refers to a collection of data or information. Optionally, the datasets are presented in a tabular pattern, wherein each column corresponds to a given variable and each row corresponds to a given member of a given dataset. Examples of the datasets include, but are not limited to, numerical datasets, bivariate datasets, multivariate datasets, categorical datasets, correlation datasets. Moreover, such datasets may be implemented as geospatial datasets (i.e., time-based data related to a specific location on Earth's surface), metatag datasets, and the like.

Optionally, the received datasets comprise at least one of: Automatic Dependent Surveillance Broadcast (ADSB) data, weather prediction data, contrail forecast data. Herein, the ADSB data represents a precise location of the at least one real-world asset, the weather prediction data represents a probability of weather conditions based on weather-based research, and contrail forecast data represents an identification of a present or future development of contrails. A technical benefit of the received datasets comprising the above-mentioned data is that this data provides a high level of insight onto the at least one real-world asset, and improves an accuracy of the digital twin.

The term “data source” refers to a memory which is configured to store at least one of or some of the plurality of datasets. Optionally, a given data source is implemented as at least one of: a data source of the system, an external data source. Herein, when the given data source is implemented as the data source of the system, data pertaining to the system is stored at the data source of the system and when the given data source is implemented as the external data source, data pertaining to the system is stored at the external data source. The plurality of data sources may comprise a Numerical Weather Prediction (NWP) data source, a General Circulation Model (GCM) data source, and the like. Moreover, the plurality of data sources are communicably coupled to sensing elements of a real-world asset corresponding to the at least one digital twin.

Throughout the present disclosure, the term “application programming interface (API)” refers to a set of functions and procedures which facilitates the at least one processor to access data and features from other devices (namely, the plurality of data sources, and the user device). Such API acts as a bridge between the at least one processor and the other devices. A given API is optionally implemented as at least one of: a public or open API, a private or internal API, a partner API, a composite API. It will be appreciated that the at least one processor is configured to receive the datasets form the plurality of data sources via the first API.

Optionally, the first API is used to query an index of the plurality of data sources, for receiving the datasets from the plurality of data sources. Herein, the term “query” refers to a request for data or information from a given data source, and the term “index” refers to a map of keys to row locations in a given dataset. Herein, the query may mark a sequence, for receiving datasets from the plurality of data sources in an order. For example, the query may mark the sequence to be: dataset 1, data source 1; dataset 2, data source 3; dataset 3, data source 2; and so on. Optionally, such indexing is performed by employing at least one of: a geospatial filter, a metatag filter, a parameter-based filter. Since the system is implemented in real-time, the at least one digital twin is required to be updated in real-time or near real-time. Moreover, when the index is queried, parameters of the query provide valid datasets.

Herein, the at least one processor utilises the first API to receive the datasets from the plurality of data sources. The at least one processor identifies the valid datasets from the plurality of data sources and assigns the sequence for receiving the same in a consumable form. A technical advantage of utilising the first API to query the index of the plurality of data sources for receiving the datasets is that the at least one processor is supplied with updated datasets at all times (i.e., in real-time or near real-time). This facilitates easy determination of datasets which are valid for a given query, and ensures that the system is efficient.

Updating of the at least one digital twin comprises removing stale data values, and replacing the stale data values with new (i.e., updated) data values. It will be appreciated that updating ensures that the at least one digital twin is a real-time virtual replica of the at least one real-world asset, since the at least one digital twin is constantly updated depending on changes of the at least one real-world asset. This allows functions to be performed on the at least one digital twin virtually, to improve performance and accuracy.

Optionally, the at least one processor is configured to update the at least one digital twin based on the received datasets, using at least one artificial intelligence technique. Herein, new information is analysed in the received datasets with respect to the at least one digital twin, and the at least one digital twin is updated using said information. For example, if the at least one digital twin represents weather conditions in San Francisco to be dry and sunny with a temperature of 40 degrees Celsius, and the received dataset indicates a hailstorm in San Francisco, the weather conditions in the at least one digital twin may be updated to now represent the hailstorm, and a reduced temperature of 10 degree Celsius.

Optionally, the at least one digital twin is updated by indexing or by running at least one data processing pipeline on data belonging to the received datasets. Indexing refers to a unique set of fields of the data, wherein the unique set of fields are combined to form a unique index on a given digital twin. For example, when data is transferred between two digital twins of two real-world assets, a local index may exist. The term “data processing pipeline” refers to a set of instructions which determine processing and transferring of the data belonging to the received datasets. It will be appreciated that the at least one data processing pipeline specifies how the received datasets are processed. Herein, the at least one data processing pipeline inputs data into the at least one digital twin. The received dataset is indexed by assigning an order for processing the data therein, identifying and extracting new data for updating the at least one digital twin. This means that, indexing indicates when (i.e., the order according to which) the received datasets are processed. Herein, the received datasets are processed, and thereby merged into a single view, in order to update the at least one digital twin. A technical advantage of such indexing is that it is efficient, and accurate.

Optionally, a given data processing pipeline comprises a sequence of data processes based at least on a type of real-world asset corresponding to the at least one digital twin. Herein, the given data processing pipeline corresponds to a plurality of received datasets, wherein the received datasets are utilised to update the at least one digital twin. Since the at least one digital twin depends on the type of corresponding real-world asset, the given data processing pipeline corresponds to the type of real-world asset as well. This means that separate data processing pipelines may be run for digital twins of separate real-world assets. For example, if a given real-world asset is a stationary asset (for example, an airport), the sequence of data processes in the given data processing pipeline may be different from when the given real-world asset is a dynamic asset (for example, an aircraft). Herein, the sequence of data processes refer to the set of instructions (preferable in an order) which process the data. Optionally, the sequence of data processed is based on: a first-in first-out approach, a priority-based approach, a size-based approach, and so forth. A technical advantage of the given data processing pipeline being based on the type of real-world asset is that the processing of data is customised, which results in an a more efficient and accurately updated digital twin, as compared to when such customisations are not utilised. Another technical advantage of this is that it allows the at least one digital twin to continuously update, increasing the scalability of the system.

Optionally, the user device is associated with a user. Herein, the user may interact with the system through the user device. Moreover, the user may provide the query for obtaining information to the user device, and then the at least one processor may receive the query therewith. Examples of the user device include, but are not limited to, a mobile phone, a computer, a laptop, and a smartwatch. The query for obtaining information refers to a request for obtaining information from the at least one digital twin. Optionally, the query for obtaining information is performed asynchronously. This means that multiple queries can be performed simultaneously. A technical advantage of asynchronous queries is that they are time-efficient since they do not require the user to wait to send queries. Moreover, another technical advantage is that the query for obtaining information can be returned in any open support format of choice, providing versatility to the system. A technical advantage of receiving the query from the user device is that it provides an accurate and easy access to the user for requesting the query. Herein, the user may be any person (such as, an administrator of the system, a business owner using the system, and the like).

Optionally, the at least one processor is configured to receive, from the user device, a customized tag associated with the query, wherein the customized tag provides extra information to facilitate processing of the query. Herein, the term “customised tag” refers to a label entailing customised information from the user. It will be appreciated that the customised tag assists in differentiating datasets on human-relatable terms. Such customised tags are based on at least one of: a geographical area, a customer, a date and time. In an example, the customised tag may be ‘London’, which covers the physical region of London. In another example, the customised tag may be UKGVT, which is customer-specific to the government of United Kingdom. Moreover, the customised tag provides additional insight for accurately processing the query. For example, a query may be to identify flights which utilise the most amount of fuel per unit distance. So, the customised tag may entail extra information, such as: amount of fuel utilized by a flight when flying close to equator, a manner in which the amount of fuel utilized by the flight varies according to an altitude of flying, or similar. It has been shown that these factors govern the fuel usage due to the gravitational pull of Earth. So, while running the query for most fuel-burning flights, longer flights which fly at a low altitude and close to the equator might be probable results. Beneficially, the customised tag assists an end-user to identify data. Examples of the customised tag include, but are not limited to, an airport, a forecast, a hindcast, a weather condition, and SO2 generation. Herein, a given customised tag may either be representative of a given received dataset, or data therein. A technical advantage of including the customised tag is this that it provides extra information that enables in accurately retrieving relevant data for processing the query, thereby resulting in more accurate and/or precise results being provided.

The query is processed by matching terms of the query with the received dataset, such as by matching terms of the query with the rows and columns in the received dataset. For example, for a query regarding flights which were cut-short, or ended abruptly, the processor may be configured to identify flights in the dataset which initially had a set destination and time of arrival, but did not arrive at the set destination at the time of arrival. Since the at least one digital twin is constantly updated with the information received from the received datasets, the query is processed at the at least one digital twin. It will be appreciated that the query is akin to a filter, which filters data from the received datasets based on at least one parameter. In an example, the query may be for flights departing from Heathrow on 20 Feb. 2020. When the query is processed, all flights matching the parameters-departing from Heathrow, and departing on 20 Feb. 2020 will be found from the received datasets. Herein, the query is initially processed to determine a validity of the query (i.e., it is ensured that the received datasets comprise said information). When it is determined that the query is valid, an index for said information is queried, and the index is received by the at least one processor. Thereafter, the at least one processor utilises the index to retrieve at least one data source comprising said information to generate the response.

Optionally, the response is generated in an open format, the open format being at least one of: a comma-separated value (CSV) format, a JavaScript Object Notation (JSON) format, a Keyhole Mark-up Language (KML) format. The CSV format is a delimited file format, which uses a comma to separate values in the file. The JSON format is a standard text-based file format for representing structured data. Examples of the JSON format include, but are not limited to, a GeoJSON format, XArrayJSON format, HJSON format, HOCON format, and JSON5 format. The KML format is a file format used to display geographic data in an Earth browser. These formats are well-known in the art. The term “open format” refers to a file format with an openly-published specification, such that it may be utilised by anyone. A technical advantage of utilising at least one of the abovementioned open formats (i.e., multiple open formats) is this that it allows multiple varied use-cases and implementations, making the system versatile.

The response is sent from the at least one processor to the user device via the second API. Since the user device is associated with the user, the user can perform a plurality of operations on the response. Such operations include, but are not limited to, displaying the response, running the response, viewing the response, deleting the response, analysing the response, and further processing of the response. For different responses received from the at least one processor, different models of interactive digital twins with different use cases can be determined.

In an exemplary scenario, a digital twin of an airplane (the at least one real-world asset) is run on the at least one processor of the system. Herein, information pertaining to the airplane may be captured using sensors and cameras, such that updated information is communicated in real-time or near real-time. For example, the sensors may be utilised to map a location of the airplane, monitor a speed of the airplane, fuel availability, path being followed, and so forth. Moreover, cameras may be installed on an outer portion of the airplane to view integral portions of the airplane (for example, the wings). The cameras may also be utilised to assess weather. Such information may be stored at a cloud-based database, and sent to the at least one processor via the first API. Thereafter, the digital twin of the airplane may be updated to accurately represent the airplane using the information. The query being received may pertain to a fuel usage at a given time during a flight, which may be processed using the digital twin to send the response, which may be 3511 litres, to the user device via the second API.

Optionally, the first API and the second API collectively provide an open multi-API specification upon which a platform for data querying is built. The open multi-API specification refers to an open source format for describing and documenting multiple APIs. Since the first API communicably connects the at least one processor to the plurality of data sources, and the second API communicably connects the at least one processor to the user device, the open multi-API specification functions as a network which connects at least: the at least one processor, the plurality of data sources and the user device. The platform for data querying provides a set of tools to facilitate building of different models for different use cases, and presenting such data onto the user device in a way that is insightful. A technical advantage of having the open multi-API specification is this that it provides a flexibility in building different models, using different formats, and so forth.

Optionally, the at least one processor is configured to send the received datasets to at least one other digital twin being run on at least one other processor, wherein the at least one processor and the at least one other processor are communicably coupled to each other. Herein, each digital twin is constantly updated based on the received datasets. Moreover, such communicable coupling between the at least one processor and the at least one other processor facilitates seamless sharing of data between the at least one digital twin and the at least one other digital twin. A plurality of digital twins run on a plurality of processors optionally send data to each other, wherein the plurality of processors are communicably coupled to each other. Herein, the at least one data processing pipeline transfers data between the at least one digital twin and the at least one other digital twin. Optionally, the at least one other processor is configured to access the digital platform for data querying. A technical advantage of such data sharing between digital twins is that all digital twins (albeit run separately by different processors), are updated with shared data in real-time. This means that, each digital twin represents data from every other digital twin, such that a given digital twin represents data from all other digital twins as well. This provides an increased level of insight into the system, and makes the given digital twin more accurate as compared to when data was not shared.

Optionally, the type of real-world asset is an aircraft, and wherein the response sent to the user device is utilized for determining carbon dioxide emissions from the aircraft and contrail data of the aircraft to subsequently propose a flight path of the aircraft. The carbon dioxide emissions and contrails negatively impact the environment. Lately, aircraft providers have to pay a fee due to the negative impact, depending on their carbon footprint. Due to this, aircraft providers now attempt to find an optimised route which would result in lower carbon dioxide emissions and lower contrail formations. It will be appreciated, that the response sent by the at least one processor to the user device is utilised to calculate the carbon dioxide emissions of formed contrails. Herein, initially, the response is utilised to determine if contrails have been formed for a given flight path. Thereon, if contrails have formed, then the carbon dioxide emission is calculated for the given flight path. Optionally, the carbon dioxide emissions from the aircraft are calculated by estimating an engine fuel consumption. In an example, an A320 aircraft may utilise 3125 litres of kerosene per hour, which is 2560 kgs of kerosene. In this example, the carbon offset emissions would be 3×engine fuel consumption per hour=3×2560=7680 kgs. Such a calculation is done for all possible flight paths, and a flight path having least amount of carbon offset emissions is proposed. A technical advantage of the response being utilised for proposing the flight path is this that the calculation of such flight paths include a lot of environments (and other) details, and require a lot of processing. Hence, calculating and proposing such flight paths using the digital twin is time-efficient, accurate and precise.

A second aspect of the invention provides a method comprising:
running at least one digital twin of at least one real-world asset;
receiving datasets from a plurality of data sources, via a first application programming interface (API);
updating the at least one digital twin, based on the received datasets;
receiving a query for obtaining information from the at least one digital twin, via a second API;
processing the query for generating a response comprising said information; and
sending the response to the user device.

A technical advantage of the method is this that utilising the first API for receiving the datasets and utilising the second API to receive the query simplifies the process by having specific functionalities dedicated to each API. This simplifies processing the query in the at least one digital twin (since digital twins have a vast amount of data), and sending the response in an efficient and accurate manner. Another technical benefit of the method is this that it can process various types of geometries and assets, in a timely manner (i.e., without any lags).

In an embodiment, the step of receiving the datasets from the plurality of data sources comprises querying an index of the plurality of data sources.

In an embodiment, the step of updating the at least one digital twin comprises indexing or running at least one data processing pipeline on data belonging to the received datasets.

In an embodiment, the method further comprises, receiving, from the user device, a customized tag associated with the query, wherein the customized tag provides extra information to facilitate processing of the query.

In an embodiment, the method further comprises sending the received datasets to at least one other digital twin.

A third aspect of the invention provides a computer program product for implementing at least one interactive digital twin, the computer program product comprising a non-transitory machine-readable data storage medium having stored thereon program instructions that, when accessed by a processing device, cause the processing device to:
run at least one digital twin of at least one real-world asset;
receive datasets from a plurality of data sources, the plurality of data sources being communicably coupled to the processing device via a first application programming interface (API);
update the at least one digital twin, based on the received datasets;
receive, from a user device, a query for obtaining information from the at least one digital twin, the user device being communicably coupled to the processing device via a second API;
process the query to generate a response comprising said information; and
send the response to the user device.

Throughout the present disclosure, the term “computer program product” refers to a software product comprising program instructions that are recorded on the non-transitory machine-readable data storage medium, wherein the software product is executable upon a computing hardware (i.e., the at least one processor).

In an embodiment, the program instructions stored on the non-transitory machine-readable data storage medium can direct the processing device to function in a particular manner, such that the processing device executes processing steps for managing data in digital twins. Examples of the non-transitory machine-readable data storage medium includes, but are not limited to, an electronic storage device, a magnetic storage device, an optical storage device, an electromagnetic storage device, a semiconductor storage device, a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, or any suitable combination thereof.

Throughout the description and claims of this specification, the words “comprise” and “contain” and variations of the words, for example “comprising” and “comprises”, mean “including but not limited to”, and do not exclude other components, integers or steps. Moreover, the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Within the scope of this application, it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible.

### BRIEF DESCRIPTION OF THE DRAWINGS

One or more embodiments of the invention will now be described, by way of example only, with reference to the following diagrams wherein:

FIG. 1 is a schematic illustration of a system, in accordance with an embodiment of the present disclosure;

FIG. 2 is an exemplary illustration of executions of, and information contained in a processor 200 of a system, in accordance with an embodiment of the present disclosure; and

FIG. 3 illustrates steps of a method, in accordance with an embodiment of the present disclosure.

### DETAILED DESCRIPTION

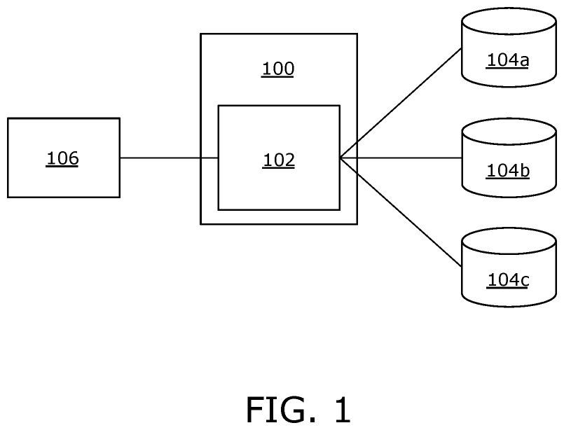

FIG. 1 is a schematic illustration of a system 100, in accordance with an embodiment of the present disclosure. The system 100 comprises at least one processor (depicted as a processor 102). The processor 102 runs at least one digital twin of at least one real-world asset. The processor 102 is communicably coupled to a plurality of data sources 104a, 104b, 104c (hereinafter collectively referred as 104). At least datasets are stored at the plurality of data sources 104. The processor 102 is communicably coupled to a user device 106. The processor 102 receives a query for obtaining information from the at least one digital twin, from the user device 106.

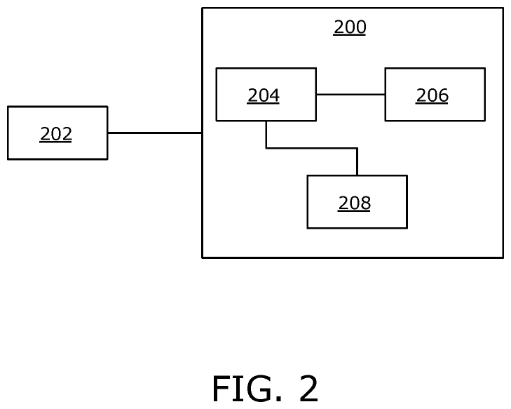

FIG. 2 is an exemplary illustration of executions of, and information contained in a processor 200 of a system, in accordance with an embodiment of the present disclosure. The processor 200 is executes the data processing pipeline 202. The data processing pipeline 202 comprises: at least one Numerical Weather Prediction (NWP) data processing pipeline, at least one General Circulation Model (GCM) data processing pipeline, at least one other data processing pipeline. The processor 200 has an index 204 of a plurality of data sources (not shown). The processor 200 executes a first application programming interface (API) 206, and a second application programming interface (API) 208. The index 204 is coupled to the first API 206 and the second API 208.

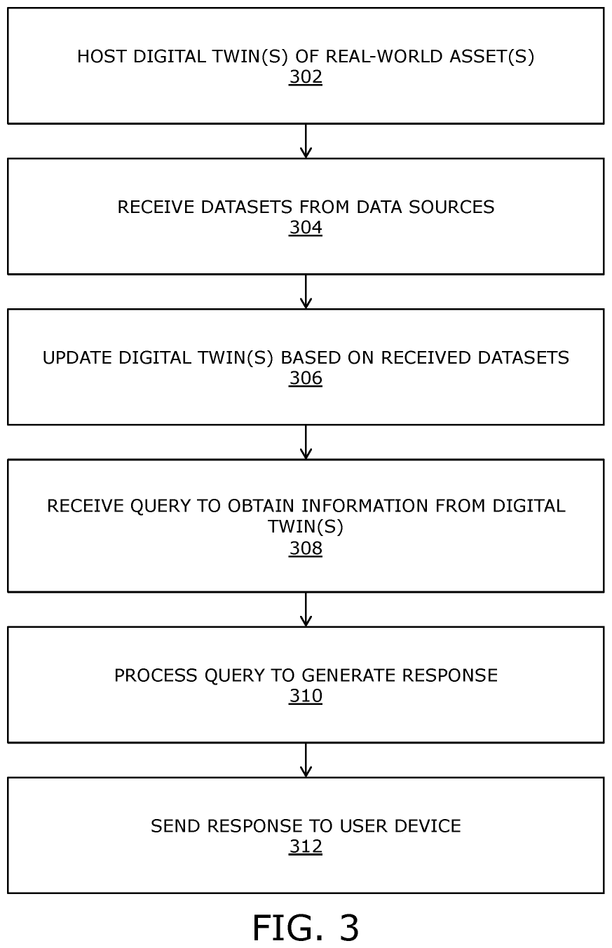

Referring to FIG. 3, illustrated are steps of a method, in accordance with an embodiment of the present disclosure. At step 302, at least one digital twin of at least one real-world asset is run. At step 304, datasets from a plurality of data sources are received, via a first application programming interface (API). At step 306, the at least one digital twin is updated, based on the received datasets. At step 308, a query for obtaining information from the at least one digital twin is received from a user device, via a second API. At step 310, the query is processed for generating a response comprising said information. At step 312, the response is sent to the user device.

The aforementioned steps are only illustrative and other alternatives can also be provided where one or more steps are added, one or more steps are removed, or one or more steps are provided in a different sequence without departing from the scope of the claims herein.

1. A system comprising at least one processor configured to: run at least one digital twin of at least one real-world asset;
receive datasets from a plurality of data sources, the plurality of data sources being communicably coupled to the at least one processor via a first application programming interface (AP!);
update the at least one digital twin, based on the received datasets; receive, from a user device, a query for obtaining information from
the at least one digital twin, the user device being communicably coupled to the at least one processor via a second API;
process the query to generate a response comprising said information; and
send the response to the user device.

2. A system of claim 1, wherein the first API is used to query an index of the plurality of data sources, for receiving the datasets from the plurality of data sources.

3. A system of claim 1, wherein the at least one digital twin is updated by indexing or by running at least one data processing pipeline on data belonging to the received datasets.

4. A system of claim 3, wherein a given data processing pipeline comprises a sequence of data processes based at least on a type of real-world asset corresponding to the at least one digital twin.

5. A system of claim 1, wherein the at least one processor is configured to receive, from the user device, a customized tag associated with the query, wherein the customized tag provides extra information to facilitate processing of the query.

6. A system of claim 1, wherein the response is generated in an open format, the open format being at least one of: a comma-separated value (CSV) format, a JavaScript Object Notation (JSON) format, a Keyhole Mark-up Language (KML) format.

7. A system of claim 1, wherein the first API and the second API collectively provide an open multi-API specification upon which a platform for data querying is built.

8. A system of claim 1, wherein the at least one processor is configured to send the received datasets to at least one other digital twin being run on at least one other processor, wherein the at least one processor and the at least one other processor are communicably coupled to each other.

9. A system of claim 1, wherein the received datasets comprise at least one of: Automatic Dependent Surveillance Broadcast (ADSB) data, weather prediction data, contrail forecast data.

10. A system of claim 4, wherein the type of real-world asset is an aircraft, and wherein the response sent to the user device is utilized for determining carbon dioxide emissions from the aircraft and contrail data of the aircraft to subsequently propose a flight path of the aircraft.

11. A method comprising:
running at least one digital twin of at least one real-world asset;
receiving datasets from a plurality of data sources, via a first application programming interface (API);
updating the at least one digital twin, based on the received datasets;
receiving a query for obtaining information from the at least one digital twin, via a second API;
processing the query for generating a response comprising said information; and
sending the response to the user device.

12. A method of claim 11, wherein the step of receiving the datasets from the plurality of data sources comprises querying an index of the plurality of data sources.

13. A method of claim 11, wherein the step of updating the at least one digital twin comprises indexing or running at least one data processing pipeline on data belonging to the received datasets.

14. A method of claim 11, further comprising receiving, from the user device, a customized tag associated with the query, wherein the customized tag provides extra information to facilitate processing of the query.

15. A computer program product for implementing at least one interactive digital twin, the computer program product comprising a non-transitory machine-readable data storage medium having stored thereon program instructions that, when accessed by a processing device, cause the processing device to:
run at least one digital twin of at least one real-world asset; receive datasets from a plurality of data sources, the plurality of
data sources being communicably coupled to the processing device via a first application programming interface (API);
update the at least one digital twin, based on the received datasets; receive, from a user device, a query for obtaining information from
the at least one digital twin, the user device being communicably coupled to the processing device via a second API;
process the query to generate a response comprising said information; and
send the response to the user device.
